(19) United States
(12) Patent Application Publication
(10) Pub. No.: US 2008/0068309 A1
(43) Pub. Date: Mar. 20, 2008

(54) Organic light emitting display device, mother substrate of the same, and method for fabricating organic light emitting display device

(76) Inventors: Won Kyu Kwak, Suwon-si (KR); Hye Jin Shin, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/806,896

(22) Filed: Jun. 5, 2007

(30) Foreign Application Priority Data
Sep. 18, 2006 (KR) 10-2006-0090129

(51) Int. Cl. G09G 3/32

(52) U.S. Cl. 345/82

(57) ABSTRACT

Organic light emitting display (OLED) devices are arrayed on a mother substrate so that testing can be performed before the mother substrate is scribed. The mother substrate includes organic light emitting display devices, a first wire group formed in a first direction at on a region between the organic light emitting display devices, a second wire group formed in a second direction on the region between the organic light emitting display devices, and at least two scribe lines formed between adjacent organic light emitting display devices of the organic light emitting display devices, where the first and second wire groups are positioned between the scribing lines not to be included inside the organic light emitting display devices.

### BACKGROUND OF THE INVENTION

1. Field of the Invention

The present embodiments relate to an organic light emitting diode (OLED) device, a mother substrate of the same, and a method for fabricating an OLED device. More particularly, the present embodiments relate to an OLED device, a mother substrate of the same, and a method for fabricating an OLED device, which performs a test of a sheet unit while preventing erroneous operation of the OLED device due to a signal delay, and improves reliability of the test by minimizing damage to wires.

2. Description of the Related Art

Generally, after multiple OLED devices are formed on a single mother substrate, they may be scribed so as to be separated into individual OLED devices. Tests of the OLED devices are typically separately performed on each OLED device which has been scribed.

Therefore, it may be advantageous to perform the tests of the multiple OLED devices on the mother substrate in a sheet unit before scribing the OLED devices. Further, it may be advantageous to perform the tests of the sheet unit without any problems due to signal delay when the tests are performed on the mother substrate. Moreover, it may be advantageous to improve the reliability of the test by minimizing the damage of wires for the sheet unit test.

The above information disclosed in this Background section is only for enhancement of understanding of the background of the invention, and therefore it may contain information that does not form the prior art that is already known in this country to a person of ordinary skill in the art.

### SUMMARY OF THE INVENTION

The present embodiments are therefore directed to an OLED device and mother substrate of the same, which substantially overcomes one or more of the problems due to the limitations and disadvantages of the related art.

It is therefore a feature of an embodiment to provide an OLED device and mother substrate of the same, in which sheet unit testing may be performed before the mother substrate is scribed.

It is therefore another feature of another embodiment to provide a mother substrate of OLED devices, where wire groups are positioned outside the OLED devices.

At least one of the above and other features and advantages of the present embodiments may be realized by providing a mother substrate including multiple OLED devices, a first wire group formed in a first direction on a region between the OLED devices, a second wire group formed in a second direction on the region between the OLED devices, and at least two scribe lines between the OLED devices, where the first and second wire groups are positioned outside the OLED devices.

The first wire group may be connected in common to the OLED devices located in a same column on the mother substrate, and the second wire group is connected in common to the OLED located in a same row on the mother substrate. The first and second wire groups may be adapted to supply power supply voltages and signals to the OLED devices. Each of the OLED devices may include a pixel portion having multiple pixels, which may include at least one OLED, and may be coupled to scan lines and data lines, a scan driver adapted to supply scan signals to the scan lines, a test section coupled to first ends of the data lines, and a data distributor coupled to second ends of the data lines. The mother substrate may include a support substrate at a lower portion of the pixel portion, a sealing substrate at an upper portion of the pixel portion, and a sealant between the support substrate and the sealing substrate. The first and second wire groups may not overlap with the sealant.

The test section may include multiple transistors, which may be coupled between predetermined wires included in the first or second wire group and the data lines, where gate electrodes of the transistors may be coupled to one wire included in the first or second wire group, whereby the transistors may be simultaneously turned-on. Respective source electrodes of the transistors may be coupled to at least one wire of the first or second wire group, and when the transistors are turned-on, the transistors may supply a test data signal to the data line. The data distributor may be adapted to maintain an off state according to a bias signal supplied from the first or second wire group. Each of the OLED devices may further include a data driver, which may be coupled to the data distributor and may be adapted to supply a data signal to respective output lines. The mother substrate may further include a first circuit section between a predetermined wire included in the first or second wire group and the scan driver, and the first circuit section may be adapted to control an OLED device connected to the first circuit section while a test is performed for at least one OLED device on the mother substrate. The first circuit section may be between the scribe lines to be outside the OLED devices. The mother substrate may include a second circuit section coupled to at least one of the scan lines, and the second circuit section may be adapted to output an output signal corresponding to a scan signal supplied to the scan line to a predetermined wire included in the first or second wire group. The second circuit section may be between the scribe lines to not be included inside the OLED devices.

At least one of the above and other features and advantages of the present embodiments may be realized by providing a method for fabricating an OLED device, which may include forming multiple OLED devices on a mother substrate, and first and second wire groups located between the OLED devices, and performing a scribing process along scribe lines of the OLED devices to scribe the OLED devices from the mother substrate, where at least two scribe lines are formed between adjacent OLED devices, and the first and second wire groups are positioned between the scribe lines.

The first and second wire groups may be outside the OLED devices. Each of the OLED devices may include at least one pixel portion. The method may include sealing a region between a support substrate at a lower portion of the pixel portion and a sealing substrate at an upper portion of the pixel portion by a sealant.

At least one of the above and other features and advantages of the present embodiments may be realized by providing an organic light emitting display device which may include a pixel portion having multiple pixels, which may include at least one organic light emitting diode, and may be coupled to scan lines and data lines, a scan driver adapted to supply scan signals to the scan lines, a test section coupled to one ends of the date lines, and a data distributor coupled between the another ends of the data lines.

The test section may include multiple transistors, which may be respectively coupled to each of the data lines. The test section may be adapted to maintain an off state according to an externally supplied control signal.

### BRIEF DESCRIPTION OF THE DRAWINGS

The above and other features and advantages of the present embodiments will become more apparent to those of ordinary skill in the art by describing in detail exemplary embodiments thereof with reference to the attached drawings, in which:

FIG. 1 illustrates an OLED device that has been scribed;

FIG. 2 illustrates a mother substrate of OLED devices according to a first embodiment;

FIG. 3 illustrates a cross-sectional view of the mother substrate taken along line A-A′ in FIG. 2;

FIG. 4 illustrates a mother substrate of OLED devices according to a second embodiment;

FIG. 5 illustrates an example of the OLED device and the wire group shown in FIG. 4;

FIG. 6 illustrates the OLED device being scribed along a scribe line shown in FIG. 4 and FIG. 5;

FIG. 7 illustrates another OLED device and the wire group shown in FIG. 4;

FIG. 8 illustrates a circuit diagram of a circuit arrangement of a first circuit section shown in FIG. 7; and

FIG. 9 illustrates a circuit diagram of a circuit arrangement of a second circuit section shown in FIG. 7.

### DETAILED DESCRIPTION OF THE INVENTION

Korean Patent Application No. 10-2006-0090129, filed on Sep. 18, 2006, in the Korean Intellectual Property Office, and entitled: “Organic Light Emitting Display Device, Mother Substrate of the Same, and Method for Fabricating Organic Light Emitting Display Device,” is incorporated by reference herein in its entirety.

The present embodiments will now be described more fully hereinafter with reference to the accompanying drawings, in which exemplary embodiments are illustrated. The embodiments may, however, be embodied in different forms and should not be construed as limited to the embodiments set forth herein. Rather, these embodiments are provided so that this disclosure will be thorough and complete, and will fully convey the scope of the embodiments to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

In the present embodiments, in an OLED device and a mother substrate of the OLED device, first and second wire groups may be included to perform a sheet unit test for multiple OLED devices on the mother substrate before the OLED devices are scribed. This may cause testing efficiency to be improved.

Furthermore, the sheet unit test may performed by directly supplying a test signal to a pixel portion through a test section, with the test signal not passing through a data distributor, which may remove problems due to a drive signal delay occurring during a test using the data distributor when the test is performed on the mother substrate.

In addition, since first and second wire groups for the sheet unit test, and circuit elements for controlling OLED devices during the sheet unit test, may be located between scribe lines of the OLED devices so as not to be included inside the OLED devices, the first wire group, the second wire group, and the circuit elements, may not overlap with a frit, which may thereby minimize any damage of wires and circuit elements, which may occur during a sealing process. This may cause the reliability of the test to be further enhanced.

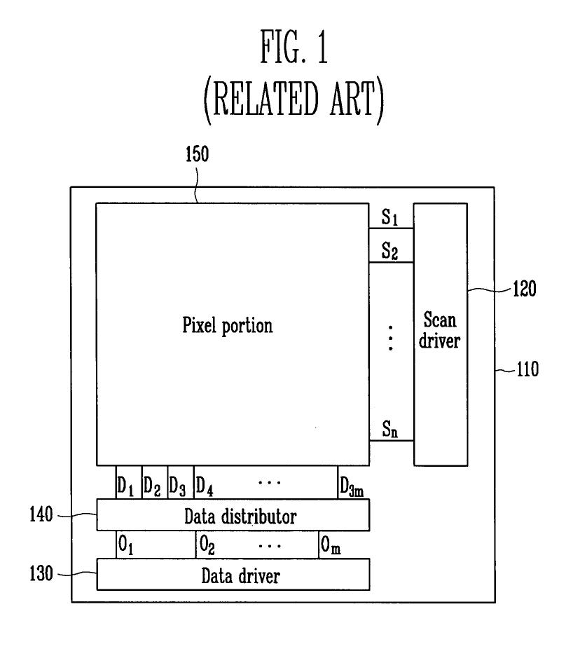

First, elements of an embodiment of a scribed OLED will be described in reference to FIG. 1. FIG. 1 illustrates an OLED device 110 that has been scribed.

Referring to FIG. 1, the OLED device 110 may include a scan driver 120, a data driver 130, a data distributor 140, and a pixel portion 150.

The scan driver 120 may generate scan signals. The scan signals generated in the scan driver 120 may be sequentially supplied to scan lines S1, S2 . . . Sn.

The data driver 130 may generate data signals. The data signals generated in the data driver 130 may be supplied to output lines O1, O2 . . . Om.

The data distributor 140 may supply the data signals, which may be supplied from the output lines O1, O2 . . . Om of the data driver 130, to at least two of the data lines D1, D2 . . . D3m. The data distributor 140 may reduce a number of channels of the data driver 130, so it may be useful for a display device having high resolution.

The pixel portion 150 may include multiple pixels (not shown), including OLEDs. The pixel portion 150 may display an image corresponding to first and second externally supplied voltages ELVDD and ELVSS, and the data signals supplied from the data distributor 140.

The tests of the OLED devices 110 may be performed in test equipment for testing the individual OLED devices. If circuit wires of the OLED devices 110 are changed, or if the sizes of the OLED devices 110 are changed, the test equipment or jigs for the test may need to be changed. Further, since the OLED devices 110 are separately tested, the test time and the cost may increase, thereby lowering the efficiency of the test.

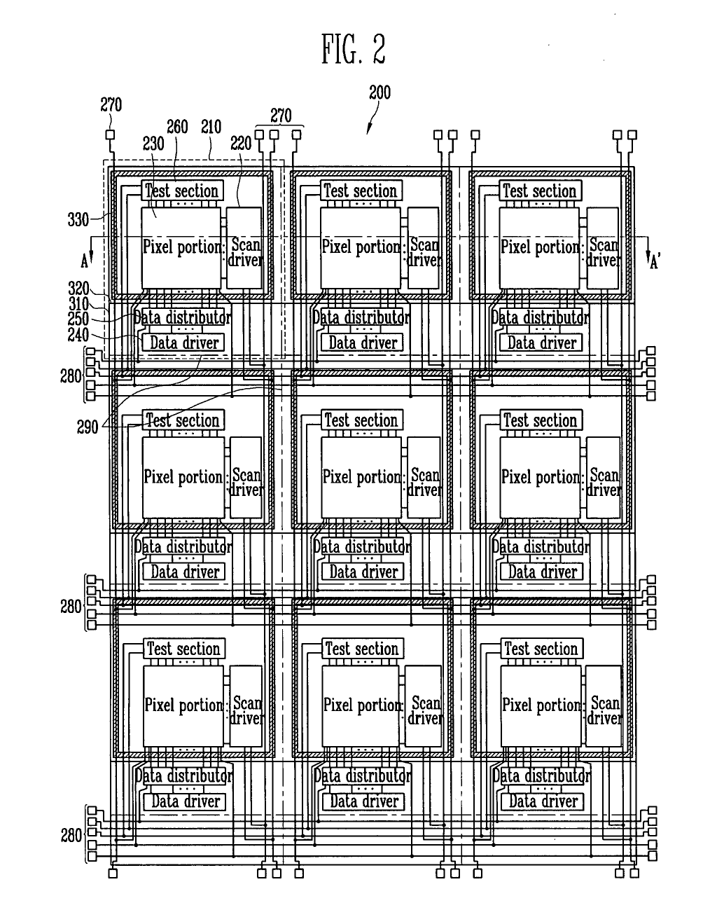

Embodiments will be described in detail with reference to FIGS. 2 to 9.

FIG. 2 illustrates a mother substrate of an OLED device according to a first embodiment.

Referring to FIG. 2, the mother substrate 200 of the OLED device may include multiple OLED devices 210 arranged in an array, a first wire group 270, and a second wire group 280.

Each of the OLED devices 210 may include a scan driver 220, a pixel portion 230, a data driver 240, a data distributor 250, and a test section 260.

The scan driver 220 may be driven according to voltages of power supplies and signals from the first wire group 270 during the sheet unit test of the mother substrate 200, and may supply scan signals to the pixel portion 230.

The pixel portion 230 may include multiple pixels (not shown), each including an OLED. During the sheet unit test, the pixel portion 230 may receive predetermined voltages supplied from the first wire group 270 and a second wire group 280, and may receive the scan signals and a test data signal from the scan driver 220 and the test section 260. When the pixel portion 230 receives the voltages of power supplies, the scan signals, and the test signal, it may display a corresponding image.

On the other hand, after the sheet unit id performed and the OLED devices 210 are scribed from the mother substrate 200, the pixel portion 230 may display an image corresponding to voltages supplied from a pad portion (not shown) employing the scan signals from the scan driver 220, and a data signal from the data distributor 250.

The data driver 240 may generate a data signal corresponding to externally supplied data after the OLED devices 210 are scribed from the mother substrate 200. The data driver 240 may be formed on the mother substrate 200, or may be mounted on each of the OLED devices 210 in a chip-type configuration after scribing.

The data distributor 250 may supply the data signals provided by each output line of the data driver 240 to three data lines of red, green, and blue sub-pixels. The data distributor 250 may reduce the number of channels of the data driver 240 and thus may be useful in a display device having high resolution. Here, for convenience, the present embodiments have been described assuming that one pixel included in the pixel portion 230 may include red, green, and blue sub-pixels. However, the present embodiments are not limited thereto.

The data distributor 250 may be set to be off during the sheet unit test for at least one OLED device 210 on the mother substrate 200. For this, the data distributor 250 may receive a bias voltage from the second wire group 280 during the sheet unit test. The data driver 240 and the data distributor 250 may be formed on the lower side of the pixel section 230, and may be connected to respective sides of data lines.

The test section 260 may receive red, green, and blue test data signals, and a test control signal from the second wire group 280. The number of the test data signals may be set to vary according to the number of sub-pixels. Further, for convenience, FIG. 2 depicts two wires formed between the test section 260 and the second wire group 280. However, in practice, the number of wires may correspond to the number of the test control signals and test data signals.

The test section 260 may provide the red, green, and blue test data signals to the red, green, and blue sub-pixels of the pixel portion 230 according to the test control signals supplied during the sheet unit test. Various test data signals may be set according to the kind of the test. The test data signal may be set as, e.g., a lighting test data signal. The test section 260 may be on the upper side of the pixel portion 230 so as to face the data driver 240 and the data distributor 250. The test section 260 may be connected to respective other sides of the data lines.

The first wire group 270 may be in a vertical direction (a first direction), and may be connected to the OLED devices 210 located in a same column on the mother substrate 200. The second wire group 280 may be formed in a horizontal direction (a second direction), and may be commonly connected to the OLED device 210 located in a same row on the mother substrate 200.

The first and second wire groups 270 and 280 may supply voltages and signals to at least one of the scan driver 220, the pixel portion 230, the data distributor 250, and the test section 260, which may be formed on the OLED devices 210, for a sheet unit test of the OLED devices 210 while on the mother substrate 200.

The OLED devices 210 may be protected from oxygen and moisture by a sealant 330. The sealant 330 may be formed between a support substrate 310 and a sealing substrate 320. The sealing substrate 320 may be positioned to overlap with at least one region of the support substrate 310. A detailed description of the sealant 330 will be explained below.

Since the mother substrate 200 of the OLED device may include the first and second wire groups 270 and 280, the sheet unit test may be performed without the OLED devices 210 on the mother substrate 200 being scribed. The tests may be performed on the OLED devices 210 connected to the first and second wire groups 270 and 280, which may be coupled to multiple OLED devices 210, by supplying voltage sources and signals for the sheet unit tests to the first and second wire groups 270 and 280. By supplying the voltage sources and signals for the sheet unit tests to the first and second wire groups 270 and 280 connected to the OLED devices 210, the tests of the OLED devices 210 on the mother substrate 200 may be performed simultaneously.

Therefore, the testing time and the associated cost may be reduced, which may thereby increase the efficiency of the test. Further, even if the circuit wires of the OLED devices 210 are changed or the size of the OLED devices 210 is changed, the test may be performed without changing test equipment or jigs as long as the size of the mother substrate and the circuit wires of the first and second wire groups 270 and 280 remain the same.

By supplying voltage sources and signals for the sheet unit tests to only the first and second wire groups 270 and 280 connected to at least one specific OLED device 210 on the mother substrate 200, the test for only the one specific OLED device may be performed. To do this, a wire supplying a first power supply voltage ELVDD to the pixel portion 230, and a wire supplying a second power supply voltage ELVSS to the pixel portion 230, may be in different directions.

The wire receiving the first power supply voltage ELVDD may be in the first wire group 270, and the wire receiving the second power supply ELVSS may be in the second wire group 280. In this case, by supplying voltage sources and signals only to the first and second wire groups 270 and 280 connected to at least one predetermined OLED device 210, it may be possible to perform a test in the predetermined OLED device 210.

When the sheet unit test has been completed, the respective OLED devices 210 formed on the mother substrate 200 may be scribed. Scribe lines 290 may be located so as to electrically separate, the first wire group 270, the second wire group 280, the scan driver 220, the pixel portion 230, the data distributor 250, and the test section 260, which may be included in the OLED device 210, after scribing. The electric contact points of the first and second wire groups 270 and 280, the scan driver 220, the pixel portion 230, the data distributor 250, and the test section 260, may be located outside the scribe lines 290 of the OLED device 210. Due to this, external noise, e.g., static electricity, introduced into the first and second wire groups 270 and 280, may not be supplied to the scan driver 220, the pixel portion 230, the data distributor 250, and the test section 260.

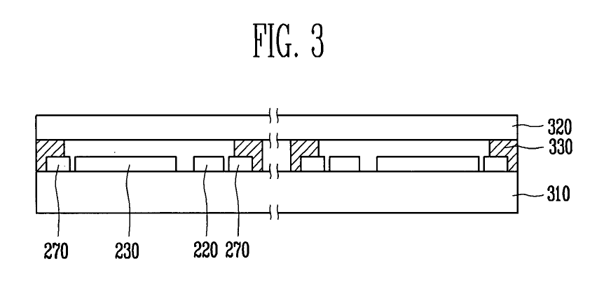

FIG. 3 illustrates a cross-sectional view of the mother substrate taken along line A-A′ in FIG. 2.

With reference to FIG. 2 and FIG. 3, each of the OLED devices 210 formed on the mother substrate 200 may include a support substrate 310, a sealing substrate 320, and a sealant 330. The support substrate 310 may be at lower portions of the pixel portion 230 and the scan driver 220. The sealing substrate 320 may be at an upper portion of the support substrate 310. The sealant 330 may be between the support substrate 310 and the sealing substrate 320.

The sealing substrate 320 may be at an upper portion of the pixel portion 230 and may adhere to the support substrate 310 by the sealant 330 in order to protect the OLED from penetration by oxygen or moisture. A sealing region sealed by the sealing substrate 320 and the sealant 330 may include at least the pixel portion 230. The sealing substrate 320 may be at upper portions of the pixel portion 230 and the scan driver 220. The sealant 330 may be coated along an edge of the sealing substrate 320 to adhere the support substrate 310 to the sealing substrate 320. That is, the sealant 330 may be formed at an outer side of the pixel portion 230 including the OLED.

Because the data driver 240 may be mounted in a chip-type configuration after being sealed, the sealing substrate 320 may be formed so as not to overlap with the data driver 240 and the data distributor 250.

When a frit is used as the sealant 330, it may form a complete seal between the support substrate 310 and the sealing substrate 320 in order to efficiently prevent oxygen and moisture from entering into the sealed region (particularly, the pixel portion 230), without using an absorbent. More particularly, a melted frit may be cured to completely seal two substrates.

The frit may be formed by, e.g., glass materials in a form of a powder including adhesives, melted glass, etc. The frit may include, e.g., transition metals. The frit may be melted by light, e.g., a visible laser, an infrared source, etc. The frit may be cured to adhere to the support substrate 310 and the sealing substrate 320, thereby completely sealing between the two substrates. Accordingly, the frit may prevent oxygen and moisture from entering between the two substrates.

The frit may include at least one of an adsorbent and a filler. The adsorbent may absorb light, e.g., from a laser, from an infrared source, etc. The filler may reduce a coefficient of thermal expansion. After a frit paste is coated and sintered on the second substrate 320, moisture or organic binder included in the paste may be eliminated, and the resulting object cured. Here, the frit paste may be formed by, e.g., adding an oxide powder and organic materials to a glass powder to produce a gel.

To transform the frit into the seal 330, a laser may be irradiated at the frit between the support substrate 310 and the sealing substrate 320 to produce the seal 330. Accordingly, when a circuit element or wire is positioned at a lower portion of the frit, the circuit element or wire may be damaged due to heat generated during the laser irradiation. For example, the circuit element or wire positioned at a lower portion of the frit may be damaged to result in, e.g., a short defect. However, in the mother substrate 200 shown in FIG. 2 and FIG. 3, the seal 330 may overlap with at least one of the first and second wire groups 270 and 280. In this case, damage, e.g., a short defect, may occur in the first and/or second wire groups 270 and 280 due to irradiation during the sealing process converting the frit to the seal 330.

As described earlier, when the first and second wire groups 270 and 280 are damaged, a sheet unit test using the first and second wire groups 270 and 280 may not be performed satisfactorily, with the result that reliability and efficiency of the test may deteriorate, and it may be impossible to perform the test itself.

For convenience, FIG. 3 shows the first wire group 270 as one wire, which may overlap the seal 330. However, in practice, multiple wires may be included in the first wire group 270. Further, FIG. 3 shows the seal 330 contacting the first wire group 270. However, at least one insulation film may be formed between the first wire group 270 and the seal 330.

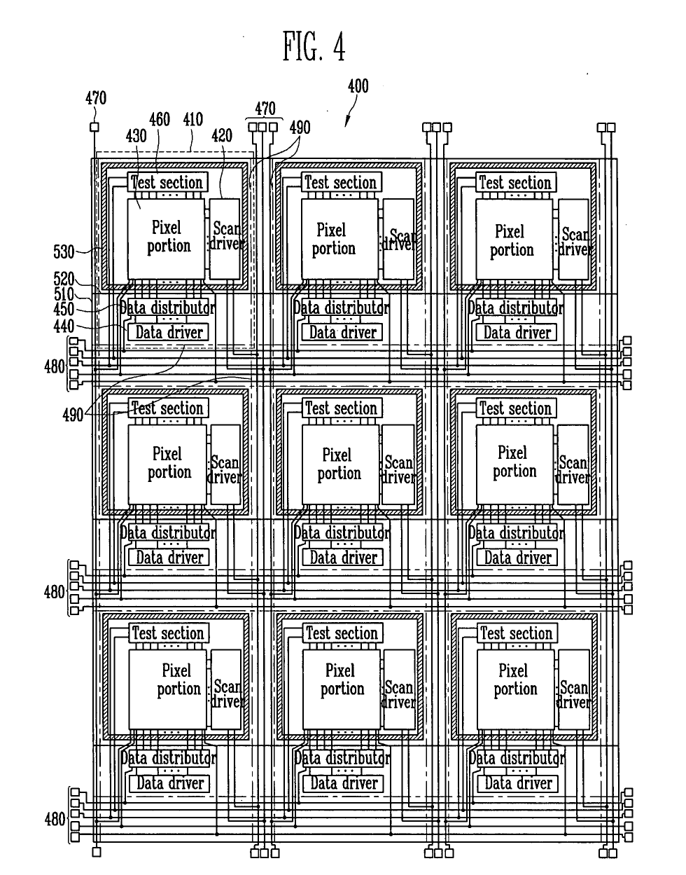

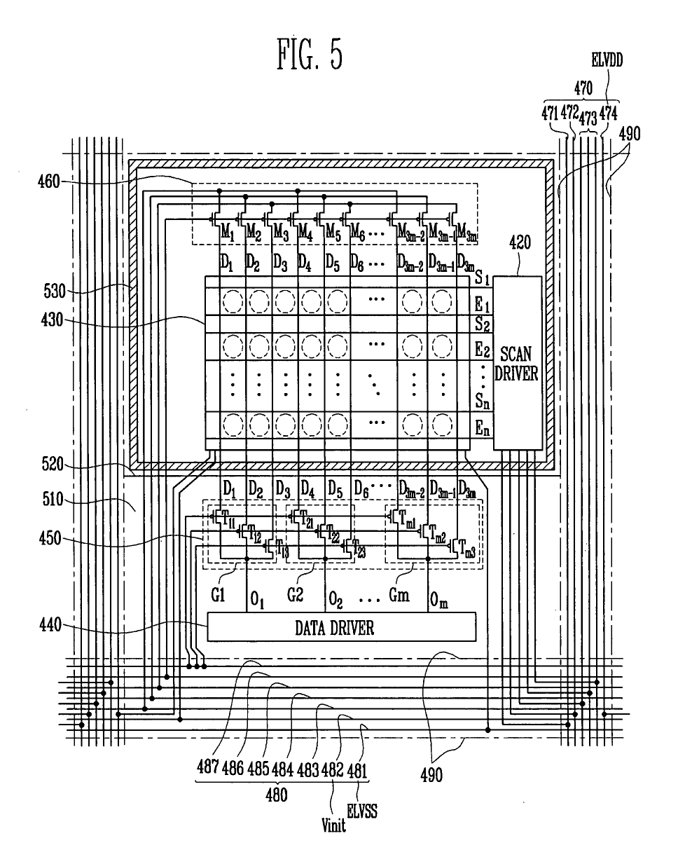

FIG. 4 illustrates a mother substrate 400 of an OLED device according to a second embodiment. FIG. 5 illustrates an example of the OLED device and the wire group shown in FIG. 4.

Referring to FIG. 4 and FIG. 5, the mother substrate 400 of the OLED device may include multiple OLED devices 410 arranged in an array, a first wire group 470, and a second wire group 480. The first wire group 470 and the second wire group 480 may be between scribe lines 490.

Each of the OLED devices 410 may include a scan driver 420, a pixel portion 430, a data driver 440, a data distributor 450, and a test section 460.

The scan driver 420 may receive a third power supply voltage VDD, a fourth power supply voltage VSS, and scan control signals from a first wire 471, a second wire 472, and third wires 473 included in the first wire group 470 for the sheet unit test on the mother substrate 400. The scan driver 420 may generate scan signals and emission control signals according to a third power supply voltage VDD, a fourth power supply voltage VSS, and the scan control signals. The scan signals and the emission control signals may be provided to the pixel portion 430 through scan lines S₁, S₂ . . . Sₙ and emission control lines E₁, E₂ . . . Eₙ.

The pixel portion 430 may include multiple pixels, which may be connected to the scan lines S₁, S₂ . . . Sₙ, the emission control lines E₁, E₂ . . . Eₙ, and data lines D₁, D₂ . . . D₃ₘ. Each of the pixels may include multiple sub-pixels including an OLED (not shown). For convenience, it is assumed that each pixel is composed of red, green, and blue sub-pixels.

While the sheet unit test using the first and second wire groups 470 and 480 on the mother substrate 400 is performed, the pixel portion 430 may receive the first power supply voltage ELVDD, the second power supply voltage ELVSS, and an initialization power supply voltage Vinit from a fourth wire 474 included in the first wire group 470, a sixth wire 481 included in the second wire group 480, and a seventh wire 482 included in the second wire group 480, respectively. The pixel portion 430 may receive scan signals and/or emission control signals, and a test data signal from the scan driver 420 and the first test section 460 during the sheet unit test. When the pixel portion 430 receives the first power supply voltage ELVDD, the second power supply voltage ELVSS, and the initialization power supply voltage Vinit, the scan signals and/or the emission control signals, and the test data signal, the pixel portion 430 may display an image corresponding thereto.

After the sheet unit test is performed and the OLED devices 410 are scribed from the mother substrate 400, the pixel portion 430 may display an image corresponding to voltages supplied from a pad portion (not shown), the scan signals and/or the emission control signals from the scan driver 420, and a data signal from the data distributor 450.

After the OLED devices 410 are scribed from the mother substrate 400, the data driver 440 may generate a data signal corresponding to externally supplied data. The data driver 440 may be formed on the mother substrate 400, or may be mounted to each of the OLED devices 410 in chip-type configuration after scribing.

After the OLED devices 410 are scribed from the mother substrate 400, the data distributor 450 may supply the data signals supplied to each output line of the data driver 440 to at least one of three data lines of the red, green, and blue sub-pixels.

As shown in FIG. 5, the data distributor 450 may include multiple group transistors G1, G2 . . . Gm, which may be connected between data lines D₁, D₂ . . . D₃ₘ and output lines O₁, O₂ . . . Oₘ of the data driver 440. The group transistors G1, G2 . . . Gm may include first transistors T₁₁, T₂₁ . . . Tₘ₁ connected to data lines D₁, D₄ . . . D₃ₘ₋₂ of the red sub-pixels, second transistors T₁₂, T₂₂ . . . Tₘ₂ connected to data lines D₂, D₅ . . . D₃ₘ₋₁ of the green sub-pixels, and third transistors T₁₃, T₂₃ . . . Tₘ₃ connected to data lines D₃, D₆ . . . D₃ₘ of the blue sub-pixels.

Here, the first transistors T₁₁, T₂₁ . . . Tₘ₁ may receive an external red clock signal, the second transistors T₁₂, T₂₂ . . . Tₘ₂ may receive a green clock signal, and the third transistors T₁₃, T₂₃ . . . Tₘ₃ receive a blue clock signal. Hereinafter, the first to third transistors T₁₁ to Tₘ₃ included in the groups of transistors G1 to Gm are each referred to as a “distribution transistor.”

The first to third distribution transistors T₁₁to Tₘ₃ may provide a data signal from output lines O₁, O₂ . . . Oₘ of the data driver 440 to the data lines D₁, D₂ . . . D₃ₘ according to the red, green, and blue clock signals. Here, the first to third distribution transistors T₁₁ to Tₘ₃ may control the red, green, and blue clock signals to cause a color image to be displayed. For example, the red, green, and blue clock signals may be supplied at different times to display the red, green, and blue images respectively. Further, they may simultaneously supply the red, green, and blue clock signals to display a white image.

The data distributor 450 may not be used during the sheet unit test using the first and second wire groups 470 and 480. If the sheet unit test is performed using the data distributor 450, the data distributor 450 may receive the red, green, and blue clock signals from the first and/or second wire groups 470 and 480.

However, the first and second wire groups 470 and 480 may be formed to be lengthy on the mother substrate 400, and a signal delay may occur while the red, green, and blue clock signals pass through the long first and second wire groups 470 and 480. As described above, when a delay occurs in the red, green, and blue clock signals, a pixel circuit may not secure a sufficient time to charge the data voltage with the result that an exact image may not be displayed. Moreover, it may be difficult to synchronize the test control signal and a test data signal with the red clock signal, the green clock signal, and the blue clock signal due to the signal delay.

Accordingly, the data distributor 450 may be set to be in an off state during the sheet unit test, and the first test section-460 may be separately provided so that the test data signal may be directly supplied to the pixel portion 430, through the test section 460, without passing through the data distributor 450.

During the sheet unit test, the data distributor 450 may receive the bias signal from twelfth wire 487 included in the second wire group 480 to turn-off the distribution transistors T₁₁ to Tₘ₃ included in the data distributor 450. That is, gate electrodes of the distribution transistors T₁₁ to Tₘ₃ may be coupled to the twelfth wire 487 and may receive a bias signal from the twelfth wire 487 during the sheet unit test. When the distribution transistors T₁₁ to Tₘ₃ receive the bias signal, they may maintain an off state. Here, the distribution transistors T₁₁ to Tₘ₃ of the data distributor 450 and the transistors M₁, M₂ . . . M₃ₘ included in the test section 460 may be coupled to each other via opposite ends of the data lines D₁, D₂ . . . D₃ₘ. When the distribution transistors T₁₁ to Tₘ₃ of the data distributor 450 are coupled to one end of the data lines D₁, D₂ . . . D₃ₘ, the transistors M₁, M₂ . . . M₃ₘ included in the test section 460 may be coupled to another end of the data lines D₁, D₂ . . . D₃ₘ.

As shown in FIG. 5, the test section 460 may include multiple transistors M₁, M₂ . . . M₃ₘ in order to perform the sheet unit test. Gate electrodes of the transistors M₁, M₂ . . . M₃ₘ may be coupled to the eleventh wire 486 included in the second wire group 480 in common.

Each source electrode of the transistors M₁, M₂ . . . M₃ₘ may be coupled to one of the eighth to tenth wires 483 to 485, and each drain electrode thereof may be coupled to one of data lines D₁, D₂ . . . D₃ₘ. Here, transistors M₁, M₄ . . . M₃ₘ₋₂ coupled to the eighth wire 483 may be coupled to data lines D₁, D₄, . . . D₃ₘ₋₂ of the red sub-pixels. Transistors M₂, M₅ . . . M₃ₘ₋₁ coupled to the ninth wire 484 may be coupled to data lines D₂, D₅ . . . D₃ₘ₋₁ of the green sub-pixels. Transistors M₃, M₆ . . . M₃ₘ coupled to the tenth wire 485 may be coupled to data lines D₃, D₆ . . . D₃ₘ of the blue sub-pixels.

During the sheet unit test, the transistors M₁, M₂ . . . M₃ₘ included in the test section 460 may be simultaneously turned-on according to a test control signal from the eleventh wire 486, and provide a test data signal from the eighth to tenth wires 483 to 485 to the respective data lines D₁, D₂ . . . D₃ₘ.

To display a predetermined color image, the test data signals, e.g., the red, green, and blue test data signals, may be supplied simultaneously or at different times to the data lines D₁, D₂ . . . D₃ₘ from the eighth to tenth wires 483 to 485 through the test section 460. That is, when the test control signal is supplied to the test section 460 through the eleventh wire 486, a color image may be displayed corresponding to supply times of the red, green, and blue test data signals to the eighth to tenth wires 483 to 485, whereby the test may be performed.

The test data signal may be variously set according to the kind of test to be performed. For example, the test data signal may be set as a lighting test data signal. The test section 460 may be formed on the upper side of the pixel portion 430 so as to face the data driver 440 and the data distributor 450, and may be connected to respective other sides of the data lines D₁, D₂ . . . D₃ₘ.

When the test is finished, the test section 460 may be set to maintain an off state according to an externally supplied control signal. After the respective OLED devices 410 are scribed from the mother substrate 400, the test section 460 may maintain the off state during normal driving and may remain only as a transistor group.

The first wire group 470 may be formed in a first direction of a region between the OLED devices 410, which may be connected in common to the OLED devices 410, which may be located in the same column on the mother substrate 400.

The first wire group 470 may include the first wire 471 to which the third source voltage VDD may be supplied, the second wire 472 to which the fourth source voltage VSS may be supplied, third wires 473 to which scan control signals may be supplied, and the fourth wire 474 to which the first source voltage ELVDD may be supplied.

The first wire 471 may supply the third source voltage VDD during the sheet unit test to the scan driver 420 in each of the OLED devices 410, which may be coupled to the first wire 471.

The second wire 472 may supply the fourth source voltage VSS during the sheet unit test to the scan driver 420 formed in each of the OLED devices 410, which may be coupled to the second wire 472.

The third wires 473 may receive the scan control signals during the sheet unit test, and may supply the scan control signals to the scan driver 420 formed in each of the OLED devices 410, which may be coupled to the third wires 473. The scan control signals may include, e.g., a clock signal, an output enable signal, a start pulse, etc., of the scan driver 420. The number of the scan control signals supplied to the scan driver 420 may be variously set according to the circuit construction of the scan driver 420. The number of the third wires 473 may therefore be determined by the circuit construction of the scan driver 420. Hereinafter, the third wires 473 may be assumed to include three wires for convenience.

The fourth wire 474 may supply the first source voltage ELVDD during the sheet unit test to the pixel portion 430 formed in each of the OLED devices 410, which may be coupled to the fourth wire 474.

The second wire group 480 may be arrayed in the second direction of the region between the OLED devices 410, which may be connected to the OLED devices 410 in common, which may be located in the same row on the mother substrate 400.

The second wire group 480 may include the sixth wire 481 to which the second source voltage ELVSS may be supplied, the seventh wire 482 to which the initializing source voltage Vinit may be supplied, the eighth wire 483 to which a red test data signal may be supplied, the ninth wire 484 to which a green test data signal may be supplied, the tenth wire 485 to which a blue test data signal may be supplied, the eleventh wire 486 to which a test control signal may be supplied, and the twelfth wire 487 to which a bias voltage may be supplied.

The sixth wire 481 may supply the second source voltage ELVSS during the sheet unit test to the pixel portion 430 formed in each of the OLED devices 410, which may be coupled to the sixth wire 481.

The seventh wire 482 may supply the initializing source voltage Vinit during the sheet unit test to the pixel portion 430 formed in each of the OLED devices 410, which may be coupled to the seventh wire 482.

The eighth wire 483 may supply the red test data signal during the sheet unit test to the test section 460 formed in each of the OLED devices 410, which may be coupled to the eighth wire 483.

The ninth wire 484 may supply the green test data signal during the sheet unit test to the test section 460 formed in each of the OLED devices 410, which may be coupled to the ninth wire 484.

The tenth wire 485 may supply the blue test data signal during the sheet unit test to the test section 460 formed in each of the OLED devices 410, which may be coupled to the tenth wire 485.

The eleventh wire 486 may supply the test control signal during the sheet unit test to the test section 460 formed in each of the OLED devices 410, which may be coupled to the eleventh wire 486.

The twelfth wire 487 may supply the bias voltage during the sheet unit test to the data distributor 450 formed in each of the OLED devices 410, which may be coupled to the twelfth wire 487.

The first and second wire groups 470 and 480 having may not be inside of the OLED devices 410, but may be located between the OLED devices 410. Namely, at least two scribe lines 490 may be set between the respective OLED devices, that is, between adjacent OLED devices 410. The first and second wire groups 470 and 480 may be positioned in at least one region between the scribe lines 490. Accordingly, the first and second wire groups 470 and 480 may be removed during the scribing process.

As explained above, by positioning the first and second wire groups 470 and 480 in the region between the scribe lines 490, the first and second wire groups 470 and 480 may be located to not overlap with the sealant 530, which may adhere the support substrate 510 to the sealing substrate 520. When the frit is used as the sealant 530, a region may be sealed between the support substrate 510 at the lower portion of the pixel portion 430 and the sealing substrate 520 positioned at the upper portion of the pixel portion 430. The pixel portion 430 may thus be protected from penetration of oxygen or moisture. Hereinafter, it is assumed that the frit may be used as the sealant 530.

The sealant 530 may be coated along an edge of the sealing substrate 520 of the OLED device 410, and may be melted and cured by a laser. As described earlier, when the first and second wire groups 470 and 480 are formed at an outer side of the OLED devices 410, the sealant 530 may not overlap with the first and second wire groups 470 and 480.

When the sealant 530 is formed not to overlap with the first and second wire groups 470 and 480, any damage of the first and second wire groups 470 and 480 due to heat may be minimized during the sealing process, which may be, e.g., laser irradiation. Accordingly, the occurrence of defects, e.g., shorts, in the first and second wire groups 470 and 480 may be prevented. This may cause reliability and efficiency of the sheet unit test to be enhanced.

Furthermore, during the sheet unit test, the test section 460 may supply red, green, and blue test data signals to the pixel portion 430 such that the data distributor 450 may maintain an off state, whereby a signal delay occurring during a test using the data distributor 450 may be eliminated.

Because the test data signal is supplied in a state that multiple transistors M₁, M₂ . . . M₃ₘ included in the test section 460 may be turned-on, the problem in that the pixel circuit does not secure a sufficient time to charge the data voltage may be solved. Moreover, since the test may be performed without passing through the data distributor 450, it may be unnecessary to synchronize the control signal and the test data signal with the red, green, and blue clock signals, thereby removing difficulties which may arise from synchronization.

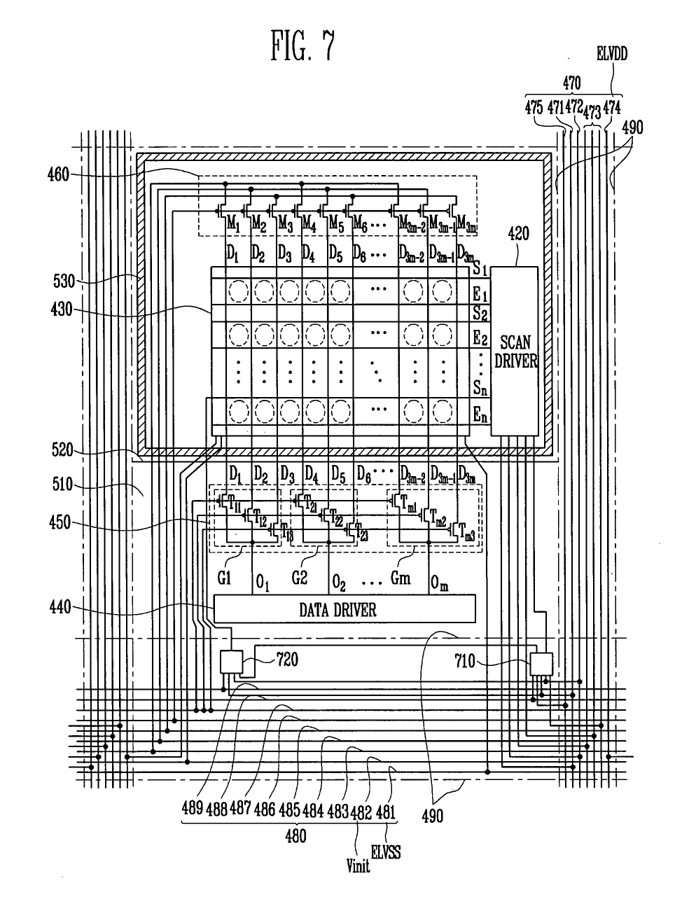

For convenience, the first to fifth wires 471 to 475 and the sixth to fourteenth wires 481 to 489 may be included in one of the first and second wire groups 470 and 480 (see FIG. 7). However, the present embodiments are not limited thereto. For example, the fourth wire 474 supplying the first power supply voltage ELVDD may be set to be included in both or one of the first and second wire groups 470 and 480.

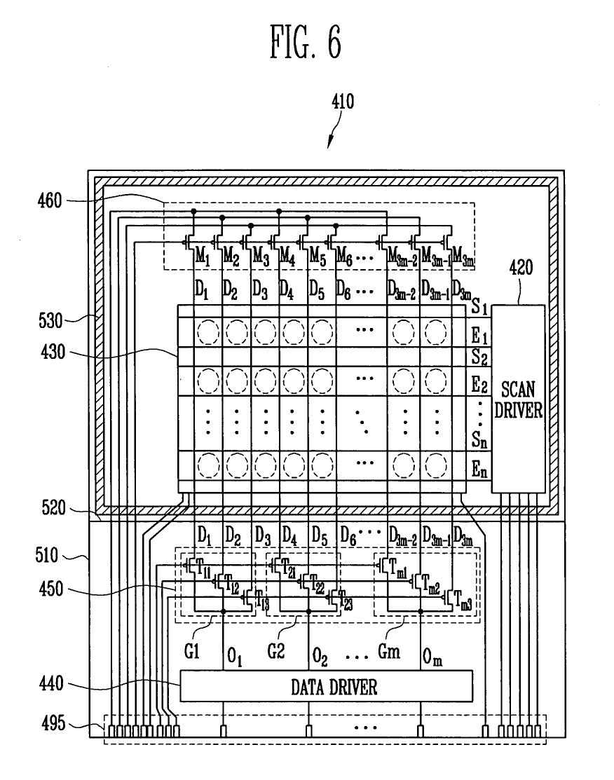

FIG. 6 illustrates an OLED device being scribed along the scribe line shown in FIG. 4 and FIG. 5.

With reference to FIG. 6, after the scribing is finished, the first and second wire groups 470 and 480 may not remain in the OLED device 410. Accordingly, damage of an internal element due to, e.g., static electricity, which may introduced through the first and second wire groups 470 and 480, may be prevented.

The test section 460 of the OLED device 410 may maintain an off state by a bias signal supplied from a pad portion 495. Further, the scan driver 420, the pixel portion 430, the data driver 440, and the data distributor 450 may be driven according to external voltages and signals supplied from an exterior through the pad portion 495.

Here, the construction of the OLED device 410 in FIG. 6 may be similar to that of the OLED device 410 shown in FIG. 4 and FIG. 5. Parts of FIG. 6 corresponding to those of FIG. 4 and FIG. 5 are designated by the same symbols and the description thereof is omitted.

A method for fabricating the OLED devices 410 will now be described.

First, as shown in FIG. 4, multiple OLED devices 410, and the first and second wire groups 470 and 480 may be formed on the mother substrate 400.

The first and second wire groups 470 and 480 may be located on a region between scribe lines 490 between the OLED devices 410 not to be included inside the OLEDs 410. To do this, at least two scribe lines may be set between adjacent OLEDs 410.

During formation of the OLED devices 410, the pixel portion 430 included in each of the OLED devices 410 may be sealed by a sealing substrate 520 and a sealant 530. The sealing substrate 520 may be at an upper portion of the pixel portion 430, and the sealant 530 may be coated along an edge of the sealing substrate 520. Here, the sealant 530, which may be the frit, may be formed to not overlap with the first and second wire groups 470 and 480. The sealant 530 may be melted and cured by a laser during the sealing process, and may adhere between the support substrate 510 and the sealing substrate 520 to completely seal the region between the support substrate 510 and the sealing substrate 520.

Next, the sheet unit test may be performed on at least one of the OLED devices 410 formed on the mother substrate 400 using the first and second wire groups 470 and 480.

When the sheet unit test on the mother substrate 400 is finished, the scribing process may be performed along scribe lines 490 to separate the OLED devices 410 from the mother substrate 400.

Because at least two scribe lines 490 may be present between the OLED devices 410 formed on the mother substrate 400, the scribing process is preferably performed twice to scribe along the two scribe lines 490. However, the present embodiments are not limited thereto. For example, the scribing process along the scribe lines 490 may be performed simultaneously.

On the other hand, circuit elements may be provided between the first and second wire groups 470 and 480 and the OLED devices 410 to control each of the OLED devices 410 during the test on the mother substrate 400.

FIG. 7 illustrates another example of the OLED devices 410 and wire group of FIG. 4. As shown in FIG. 7, first and second circuit sections 710 and 720 may be between the first and second wire groups 470 and 480 and the OLED devices 410. The first circuit section 710 may be a circuit for the sheet unit test. When the sheet unit test is performed for at least one OLED device 410 on the mother substrate 400, the first circuit section 710 may function to independently control on/off states of the respective OLED devices 410.

The first circuit section 710 may receive a vertical control signal VC, a horizontal control signal HC, a scan control signal SCS, and the third and fourth power supply voltages VDD and VSS The first circuit section 710 may thus control the scan driver 420, thereby controlling the on/off states of the respective OLED devices 410.

The first wire group 470 further may include a fifth wire 475 for supplying the vertical control signal VC, and the second wire group 480 may include an thirteenth wire 488 for supplying the horizontal control signal HC.

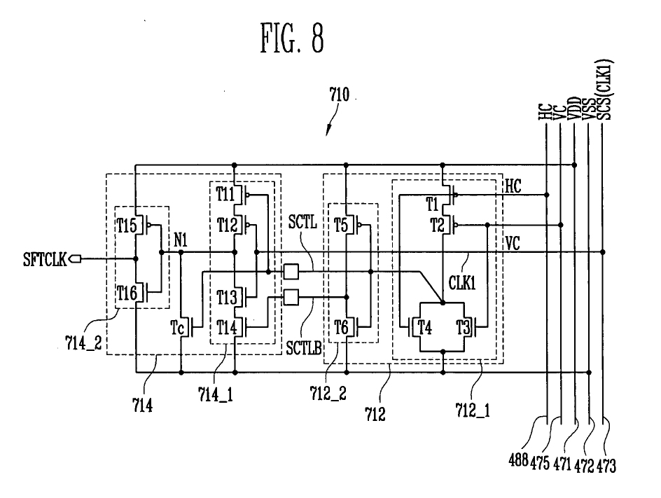

FIG. 8 illustrates a circuit diagram of a circuit arrangement of the first circuit section shown in FIG. 7. The first circuit section 710 may include a shift control signal generator 712 and a shift clock signal generator 714, as shown in FIG. 8.

The shift control signal generator 712 may include a NOR gate 712_1 and an inverter 712_2. The NOR gate 712_1 may include first to fourth transistors T1 to T4, which may be coupled between the third power supply voltage VDD and the fourth power supply voltage VSS.

More particularly, the first and second transistors T1 and T2 may be coupled in series between the third power supply voltage VDD and the fourth power supply voltage VSS, and may each be formed of a P-type transistor. The third and fourth transistors T3 and T4 may be coupled in parallel between the second transistor T2 and the fourth power supply voltage VSS, and may each be formed of a N-type transistor. Gate electrodes-of the first and fourth transistors T1 and T4 may be coupled to the thirteenth wire 488, and receive the horizontal control signal HC. Gate electrodes of the second and third transistors T2 and T3 may be coupled to the fifth wire 475 and may receive the vertical control signal VC.

When both of a low level horizontal control signal HC and a low level vertical control signal VC are supplied to the NOR gate 712_1, it may output a signal having a high level voltage corresponding to the third power supply VDD, and an output signal of the NOR gate 712_1 is used as a first shift control signal SCTL.

The inverter 712_2 may include fifth and sixth transistors T5 and T6 connected in series between the third power supply voltage VDD and the fourth power supply voltage VSS. The fifth and sixth transistors T5 and T6 may be of different conductive types. Gate electrodes of the fifth and sixth transistors T5 and T6 may be coupled to an output terminal of the NOR gate 712_1.

The inverter 712_2 may invert an output signal (namely, first shift control signal SCTL) of the NOR gate 712_1 to generate a second shift control signal SCTLB.

The shift clock signal generator 714 may include a tristate inverter 714_1, a control transistor Tc, and an inverter 714_2.

The tristate inverter 714_1 may include eleventh to fourteenth transistors T11 to T14, which may be connected in series between the third power supply voltage VDD and the fourth power supply voltage VSS. The eleventh and twelfth transistors T11 and T12 may be P-type transistors, whereas the thirteenth and fourteenth transistors T13 and T14 may be N-type transistors. A gate electrode of the eleventh transistor T11 may be coupled with an output terminal of the NOR gate 712_1 of the shift control signal generator 712, and may receive the first shift control signal SCTL. Gate electrodes of the twelfth and thirteenth transistors T12 and T13 may be coupled with one of the third wires 473 receiving the scan control signal SCS, and may receive a first clock signal CLK1. A gate electrode of the fourteenth transistor T11 may be coupled with an output terminal of the inverter 712_2 included in the shift control signal generator 712, and may receive the second shift control signal SCTLB.

The control transistor Tc may be coupled between a first node NI, being an output terminal of the tristate inverter 714_1, and the fourth power supply VSS, and may be a N-type transistor. A gate electrode of the control transistor Tc may be coupled with an output terminal of the NOR gate 712_1, and may receive the first shift control signal SCTL.

The inverter 714_2 may include fifteenth and sixteenth transistors T15 and T16 of different conductive types, which may be between the third and fourth power supply voltages VDD and VSS in series. Here, gate electrodes of the fifteenth and sixteenth transistors T15 and T16 may be coupled to the first node N1 in common.

When the first shift control signal SCTL of a high level and the second shift control signal SCTLB of a low level are supplied to the shift clock signal generator 714, it may generate a first shift clock signal SFTCLK of a high level regardless of the first clock signal CLK1. Further, when the first shift control signal SCTL of a low level and the second shift control signal SCTLB of a high level are supplied to the shift clock signal generator 714, it may generate the first shift clock signal SFTCLK having the same waveform as that of the first clock signal CLK1.

The shift clock signal generator 714 further may also include a second shift clock signal SFTCLKB (having a waveform opposite to that of the first shift clock signal SFTCLK) generation circuit (not shown) in order to generate the second shift clock signal SFTCLKB.

When the horizontal control signal HC and the vertical control signal VC have a low level voltage value, the first circuit section 710 may generate the first shift control signal SCTL of a high level and a second shift control signal SCTLB of a low level, and the first circuit section 710 may generate the first and second shift clock signals SFTCLK and SFTCLKB of a high level regardless of the first clock signal CLK1 using the first shift control signal SCTL and the second shift control signal SCTLB.

The first and second shift clock signals SFTCLK and SFTCLKB of a high level generated by the first circuit section 710 may control the scan driver 420. In this case, the scan driver 420 may generate scan signals and/or emission control signals to turn-off the pixel portion 430, thereby causing the OLED device 410 to be turned-off.

In other cases, namely, in cases except for the case when the horizontal control signal HC and the vertical control signal VC have a low level, the first circuit section 710 may generate and provide the first shift clock signal SFTCLK having the same waveform as that of the first clock signal CLK1 to the scan driver 420, so that a test in the OLED device 410 may be performed.

During the testing of the multiple OLED devices 410 on the mother substrate 400, when a specific OLED device 410 is erroneously operated, the first circuit section 710 may individually turn-off the OLED device 410 being erroneously operated, so that the test of other OLED devices 410 may be normally performed.

The second circuit section 720 may be a measuring circuit. While the test is performed with at least one OLED device 410 on the mother substrate 400, the second circuit section 720 may measure a generation or non-generation of a normal scan signal and power consumption of the scan driver 410 by receiving and measuring a scan signal, which may be generated by the scan driver 420 of the OLED device 410 in which a test is being performed, and may be provided to the pixel portion 430. To do this, the second circuit section 720 may be coupled between one of the scan lines S₁, S₂ . . . Sₙ and the first and second wire groups 470 and 480.

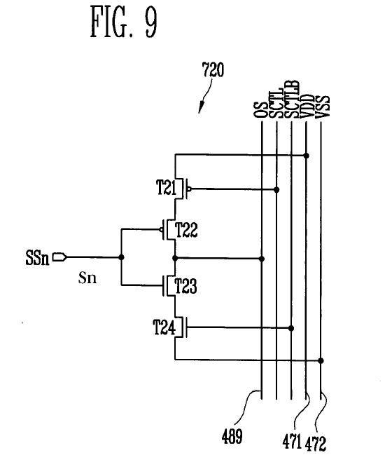

FIG. 9 illustrates a circuit diagram of a second circuit section shown in FIG. 7. More particularly, the second circuit section 720 may include a tristate inverter, which may be coupled between the third power supply VDD and the fourth power supply VSS.

The tristate inverter may include twenty-first to twenty-fourth transistors T21 to T24, which may be connected in series between the third power supply voltage VDD and the fourth power supply voltage VSS. Here, the twenty-first and twenty-second transistors T21 and T22 may be P-type transistors, and the twenty-third and twenty-fourth transistors T23 and T24 may be N-type transistors. A gate electrode of the twenty-first transistor T21 may be coupled to the first circuit section 710, and may receive the first shift control signal SCTL. Gate electrodes of the twenty-second and twenty-third transistors T22 and T23 may be coupled to the n-th scan line Sn, and may receive an n-th scan signal SSn. A gate electrode of the twenty-fourth transistor T24 may be coupled with the first circuit section 710, and may receive the second shift control signal SCTLB.

While the test is performed on the mother substrate 400, when the OLED device 410 coupled to the second circuit section 720 is normally operated (namely, a case except when the first shift control signal SCTL has a high level and the shift control signal SCTLB has a low level), the second circuit section 720 may output an output signal OS corresponding to the n-th scan signal SSn to the fourteenth wire 489. To do this, the second wire group 480 further may include the fourteenth wire 489, which may receive the output signal OS of the second circuit section 720.

When generation circuits for the first and second shift control signal SCTL, SCTLB are not included in the first circuit section 710, the second circuit section 720 may receive the first and second shift control signals SCTL and SCTLB from the first wire group 470 or the second wire group 480.

In the same manner as in the first and second wire groups 470 and 480, the first and second circuit sections 710 and 720 may be between scribe lines 490 so as not to be included inside the OLED devices 410. This may prevent the first and second circuit sections 710 and 720 from being damaged during sealing.

For convenience, FIG. 8 and FIG. 9 show arbitrary directions of the signal lines. However, the signal lines may be formed in different directions. For example, the tenth wire 485 for receiving the vertical control signal VC may be included in the first wire group 470 and may be formed in the first direction (vertical direction). Further, the thirteenth wire 488 for receiving the horizontal control signal HC may be included in the second wire group 480 and may be formed in the second direction (horizontal direction).

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present embodiments as set forth in the following claims.

What is claimed is:

1. A mother substrate, comprising:
a plurality of organic light emitting display devices;
a first wire group formed in a first direction on a region between the organic light emitting display devices;
a second wire group formed in a second direction on the region between the organic light emitting display devices; and
at least two scribe lines between the organic light emitting display devices,
wherein the first and second wire groups are positioned outside the organic light emitting display devices.

2. The mother substrate as claimed in claim 1, wherein the first wire group is connected in common to the organic light emitting display devices located in a same column on the mother substrate; and
the second wire group is connected in common to the organic light emitting display located in a same row on the mother substrate.

3. The mother substrate as claimed in claim 2, wherein the first and second wire groups are adapted to supply power supply voltages and signals to the organic light emitting display devices.

4. The mother substrate as claimed in claim 1, wherein each of the organic light emitting display devices includes:
a pixel portion having a plurality of pixels, which include at least one organic light emitting diode, and are coupled to scan lines and data lines;
a scan driver adapted to supply scan signals to the scan lines;
a test section coupled to first ends of the data lines; and
a data distributor coupled to second ends of the data lines.

5. The mother substrate as claimed in claim 4, further comprising:
a support substrate at a lower portion of the pixel portion;
a sealing substrate at an upper portion of the pixel portion; and
a sealant between the support substrate and the sealing substrate.

6. The mother substrate as claimed in claim 5, wherein the first and second wire groups do not overlap with the sealant.

7. The mother substrate as claimed in claim 4, wherein the test section includes a plurality of transistors, which are coupled between predetermined wires included in the first or second wire group and the data lines,
wherein gate electrodes of the transistors are coupled to one wire included in the first or second wire group, whereby the transistors are simultaneously turned-on.

8. The mother substrate as claimed in claim 7, wherein respective source electrodes of the transistors are coupled to at least one wire of the first or second wire group, and when the transistors are turned-on, the transistors supply a test data signal to the data line.

9. The mother substrate as claimed in claim 4, wherein the data distributor is adapted to maintain an off state according to a bias signal supplied from the first or second wire group.

10. The mother substrate as claimed in claim 4, wherein each of the organic light emitting display devices further includes a data driver, which is coupled to the data distributor and is adapted to supply a data signal to respective output lines.

11. The mother substrate as claimed in claim 4, further comprising a first circuit section between a predetermined wire included in the first or second wire group and the scan driver, and the first circuit section is adapted to control an organic light emitting display device connected to the first circuit section while a test is performed for at least one organic light emitting display device on the mother substrate.

12. The mother substrate as claimed in claim 11, wherein the first circuit section is between the scribe lines to be outside the organic light emitting display devices.

13. The mother substrate as claimed in claim 4, further comprising a second circuit section coupled to at least one of the scan lines, and the second circuit section is adapted to output an output signal corresponding to a scan signal supplied to the scan line to a predetermined wire included in the first or second wire group.

14. The mother substrate as claimed in claim 13, wherein the second circuit section is between the scribe lines to not be included inside the organic light emitting display devices.

15. A method for fabricating an organic light emitting display device, comprising:
forming a plurality of organic light emitting display devices on a mother substrate, and first and second wire groups located between the organic light emitting display devices; and
performing a scribing process along scribe lines of the organic light emitting display devices to scribe the organic light emitting display devices from the mother substrate,
wherein at least two scribe lines are formed between adjacent organic light emitting display devices, and the first and second wire groups are positioned between the scribe lines.

16. The method as claimed in claim 15, wherein the first and second wire groups are outside the organic light emitting display devices.

17. The method as claimed in claim 15, wherein each of the organic light emitting display devices includes at least one pixel portion.

18. The method as claimed in claim 17, further comprising sealing a region between a support substrate at a lower portion of the pixel portion and a sealing substrate at an upper portion of the pixel portion by a sealant.

19. An organic light emitting display device comprising:
a pixel portion having a plurality of pixels, which include at least one organic light emitting diode, and are coupled to scan lines and data lines;
a scan driver adapted to supply scan signals to the scan lines;
a test section coupled to one ends of the date lines; and
a data distributor coupled between the another ends of the data lines.

20. The organic light emitting display device as claimed in claim 19, wherein the test section includes a plurality of transistors, which are respectively coupled to each of the data lines.

21. The organic light emitting display device as claimed in claim 19, wherein the test section is adapted to maintain an off state according to an externally supplied control signal.
